(19) United States
(12) Patent Application Publication
(10) Pub. No.: US 2014/0167123 A1
(43) Pub. Date: Jun. 19, 2014

(54) POWER SEMICONDUCTOR DEVICE AND METHOD OF MANUFACTURING THE SAME

(71) Applicant: SAMSUNG ELECTRO-MECHANICS CO., LTD., Suwon (KR)

(72) Inventors: Kwang Soo KIM, Suwon (KR); Bum Seok SUH, Suwon (KR); In Wha JEONG, Suwon (KR); Ji Hyun PARK, Suwon (KR); Jaehoon PARK, Suwon (KR)

(73) Assignee: SAMSUNG ELECTRO-MECHANICS CO., LTD., Suwon (KR)

(21) Appl. No.: 14/100,949

(22) Filed: Dec. 9, 2013

(30) Foreign Application Priority Data
Dec. 13, 2012 (KR) 10-2012-0145167

(51) Int. Cl. H01L 29/417; H01L 21/28; H01L 29/78

(52) U.S. Cl. CPC H01L 29/41725; H01L 29/78; H01L 21/28
USPC 257/288; 438/197

(57) ABSTRACT

There is provided a power semiconductor device including: a body region having a first conductivity; a well formed in an upper portion of the body region and having a second conductivity; and a conductive via formed in the body region while traversing the well.

### CROSS-REFERENCE TO RELATED APPLICATION

This application claims the benefit of Korean Patent Application No. 10-2012-0145167 filed on Dec. 13, 2012, with the Korean Intellectual Property Office, the disclosure of which is incorporated herein by reference.

### BACKGROUND

The present disclosure relates to a power semiconductor device and a method of manufacturing the same.

A metal oxide semiconductor field effect transistor (MOSFET) is the most generally employed type field effect transistor (FET) in digital and analog circuits.

A metal oxide semiconductor (MOS) structure is obtained by stacking a depletion layer formed of silicon dioxide (SiO₂), a metal layer, or a polysilicon layer on a semiconductor substrate.

Since the silicon dioxide is a dielectric material, the MOS structure is a structure in which one of two metal electrodes of a parallel plate capacitor is replaced by a semiconductor.

When a voltage is applied to the MOS structure, a distribution of charges in a portion in which the semiconductor substrate and the silicon dioxide contact each other is changed.

That is, when a positive (+) voltage is applied to the MOS structure, a concentration of holes of a p-type semiconductor tends to be decreased, while a concentration of electrons thereof tends to be increased.

When the positive (+) voltage is sufficiently high, a region in which a concentration of electrons is significantly higher than that of holes is formed in a location close to a gate. This region is commonly known as an inversion layer.

Next, an operational principle of the MOSFET will be described. In the case in which a voltage applied to a gate of the MOSFET is lower than a threshold voltage of a device, the inversion layer is not formed.

Therefore, the transistor is turned off depending on a basic threshold model, such that conduction between a drain and a source does not occur.

In the case in which the voltage applied to the gate of the MOSFET is higher than the threshold voltage of the device, a concentration of electrons is increased in a p-type body layer in a location adjacent to the gate, such that the inversion layer is formed.

Therefore, when the transistor is turned on and a channel is formed, a current flows between the drain and the source.

In this case, the MOSFET is operated, in a similar manner to a resistor controlled by a gate voltage, associated with source and drain voltages, and has current linearly increased therein as a voltage is increased.

As types of MOSFET, there are provided double gate MOSFETs, depletion type MOSFETs, NMOS logic gates, power MOSFETs, and the like.

Among these types of MOSFET, power MOSFETs may maintain a high voltage and a high current. Therefore, a range of fields to which power MOSFETs are applicable has recently increased.

Power MOSFETs have a vertical structure in order to maintain high voltages and high currents.

Power MOSFETs have better communication speeds and efficiency at low voltages, as compared with other power semiconductor devices (for example, insulated gate bipolar transistors, thyristors, and the like).

Insulated gate bipolar transistors may be used at high voltages, since holes provided in a collector cause conductivity modulation. However, it may be difficult to use MOSFETs at high voltages, since turn-on resistance is rapidly increased in a body region of a device in the case in which voltages are increased.

Therefore, power MOSFETs capable of having greater switching speeds than those of other power semiconductor devices and able to be used with high voltages has been demanded.

The invention of the following Related Art Document (Patent Document 1), which relates to an insulated integrated circuit (IC) device having a via hole filled with a dielectric material and having a compact insulated structure, and a method of manufacturing the same, is different and distinguishable from that of the present disclosure.

### RELATED ART DOCUMENT

(Patent Document 1) Korean Patent Laid-Open Publication No. 2010-0132953

### SUMMARY

An aspect of the present disclosure may provide a power semiconductor device having a rapid switching speed and able to be used with high voltages.

Another aspect of the present disclosure may provide a power semiconductor device capable of being used even at high voltages, by decreasing turn-on resistance in a body region.

According to an aspect of the present disclosure, a power semiconductor device may include: a body region having a first conductivity; a well formed in an upper portion of the body region and having a second conductivity; and a conductive via formed in the body region while traversing the well.

The conductive via may provide a path along which current flows when the power semiconductor device is turned on.

The conductive via may be formed to penetrate through the body region.

The power semiconductor device may further include a via insulating film formed between the conductive via and the body region.

The conductive via may be formed of at least one of polysilicon and a metal.

The power semiconductor device may further include a source region formed at an upper portion of the body region, spaced apart from the well, and having the second conductivity.

The power semiconductor device may further include a gate part on the well, the body region, and the source region.

The power semiconductor device may further include a drain region formed in a lower portion of the body region.

The first conductivity and the second conductivity may be a p-type and an n-type, respectively.

According to another aspect of the present disclosure, a method of manufacturing a power semiconductor device may include: preparing a body region having a via hole formed therein and having a first conductivity; implanting impurities having a second conductivity into a portion of a surface of the body region in which a well is formed to form a source region; filling the via hole with polysilicon or metal to form a conductive via; and forming a gate part on the conductive via and the body region.

The conductive via may provide a path along which current flows when the power semiconductor device is turned on.

The method may further include removing a rear surface of the body region so that the conductive via is formed to penetrate through the body region.

The method may further include forming a via insulating film between the conductive via and the body region.

The method may further include, after the forming of the gate part, forming a drain region in a lower portion of the body region.

The first conductivity and the second conductivity may be n-type conductivity and p-type conductivity, respectively.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic cross-sectional view of a power semiconductor device according to an exemplary embodiment of the present disclosure; and

FIGS. 2A through 2G are views showing a process of manufacturing a power semiconductor device according to the exemplary embodiment of the present disclosure.

### DETAILED DESCRIPTION

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

A power switch may be implemented by any one of a power metal oxide semiconductor field effect transistor (MOSFET), an insulated gate bipolar transistor (IGBT), several types of thyristor, and devices similar to the above-mentioned devices.

Most of new technologies disclosed herein will be described based on the MOSFET.

However, several exemplary embodiments of the present disclosure disclosed herein are not limited to the MOSFET, but may also applied to other types of power switch technologies including an IGBT and several types of thyristors in addition to a diode.

Further, several exemplary embodiments of the present disclosure will be described as including specific p-type and n-type regions.

However, conductivities of several regions disclosed herein may be similarly applied to devices having conductivities opposite thereto.

In addition, an n-type or a p-type used herein may be defined as a first conductivity or a second conductivity. Meanwhile, first and second conductivities are different conductivities.

Further, ‘+’ generally means a state in which a region is heavily doped and ‘−’ means the state in which a region is lightly doped.

Hereinafter, a power semiconductor device according to an exemplary embodiment of the present disclosure will be described with reference to the accompanying drawings.

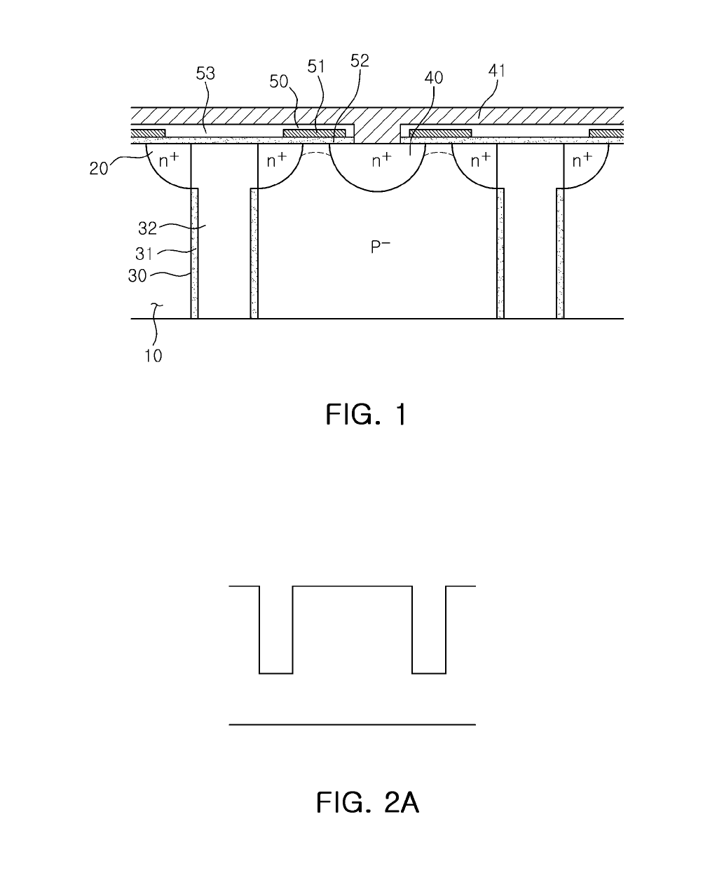

FIG. 1 is a schematic cross-sectional view of a power semiconductor device according to an exemplary embodiment of the present disclosure.

Referring to FIG. 1, the power semiconductor device according to the exemplary embodiment of the present disclosure may include a body region 10 having a first conductivity; a well 20 formed at an upper portion of the body region 10 and having a second conductivity; and a conductive via 30 formed in the body region 10 while traversing the well 20.

The conductive via 30 may provide a path along which a current may flow when the power semiconductor device is turned on.

When a general MOSFET is turned on, a current may flow through the body region.

The turning on of the power semiconductor device may occur when a gate voltage of the power semiconductor device is higher than a threshold voltage of the power semiconductor device and be divided into a linear region in which current flow is increased in proportion to an increase in a voltage and a saturated region in which current flow is not increased in proportion to an increase in a voltage.

The saturated region may be formed due to loss generated in the body region.

Therefore, the conductive via 30 provides a low resistance path along which a current may flow at the time of the turn-on operation of the power semiconductor device, whereby the power semiconductor device according to the exemplary embodiment of the present disclosure may be driven even at high voltages.

The conductive via 30 may be formed to penetrate through the body region 10.

That is, when the conductive via 30 is formed to penetrate through the body region 10, since a current does not flow to the body region 10 having a relatively high resistance, efficiency of the power semiconductor device may be further increased.

The power semiconductor device according to the exemplary embodiment of the present disclosure may further include a via insulating film 31 formed between the conductive via 30 and the body region 10.

The conductive via 30 may be separated from the body region 10 by the via insulating film 31 and have a gate insulating film 52 formed thereon to thereby be separated from a gate part 50.

Therefore, the conductive via 30 may contact the well 20 having the first conductivity.

The conductive via 30 may be formed of at least one of polysilicon and a metal.

The conductive via 30 may be formed of a material having a resistance lower than that a material of the body region 10.

The metal may have a resistance significantly lower than that of the polysilicon. However, in a process of manufacturing a device using the metal, a high temperature heat treatment needs to be performed, such that there is a limitation at the time of using the metal.

Although the polysilicon has a resistance higher than that of the metal, it may easily control a threshold voltage, a resistance, and the like, using a concentration of impurities.

The power semiconductor device according to the exemplary embodiment of the present disclosure may further include a source region 40 formed at an upper portion of the body region 10, spaced apart from the well 20, and having the second conductivity.

The well 20 and the source region 40 may be spaced apart from each other by the body region 10.

Since the body region 10 has conductivity different from those of the well 20 and the source region 40 and has a low impurity concentration, in the case in which a voltage is not applied to the gate part 50, a current may not flow between the source region 40 and the well 20.

The power semiconductor device according to the exemplary embodiment of the present disclosure may further include the gate part 50 on the well 20, the body region 10, and the source region 40.

The gate part 50 may include the gate insulating film 52 formed in a lower portion thereof, polysilicon 51 formed on the gate insulating film 52, and a dielectric layer 53 formed on the polysilicon 51.

When a positive (+) voltage is applied to the gate part 50, electrons may be attracted to a portion of the body region 10 adjacent to the gate part 50.

That is, an inversion layer may be formed as shown by dotted lines in FIG. 1, and a current may flow through the inversion layer.

The power semiconductor device according to the exemplary embodiment of the present disclosure may further include a drain region formed in a lower portion of the body region 10.

The first conductivity and the second conductivity may be p-type conductivity and n-type conductivity, respectively, and vice versa.

In addition, a concentration of the conductivity may be appropriately controlled if necessary.

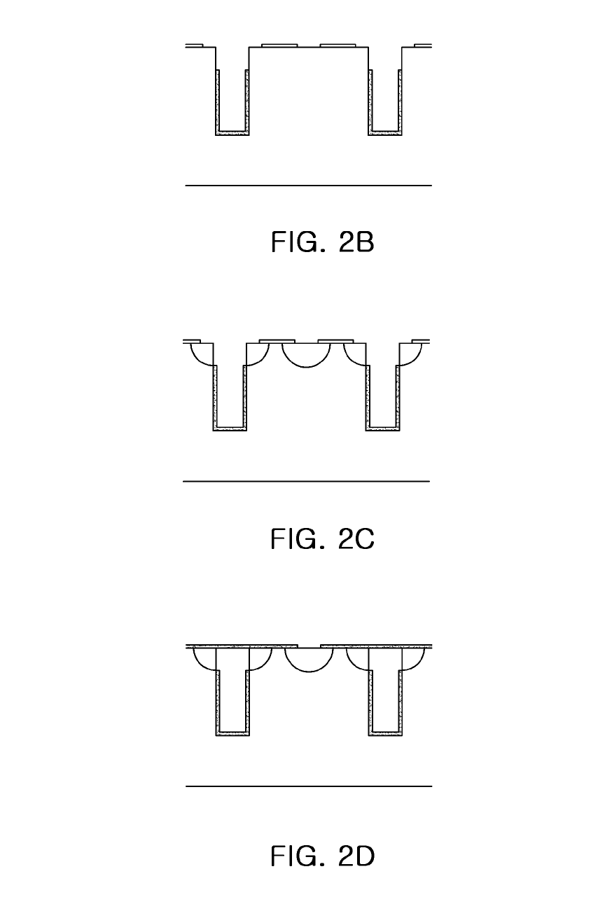

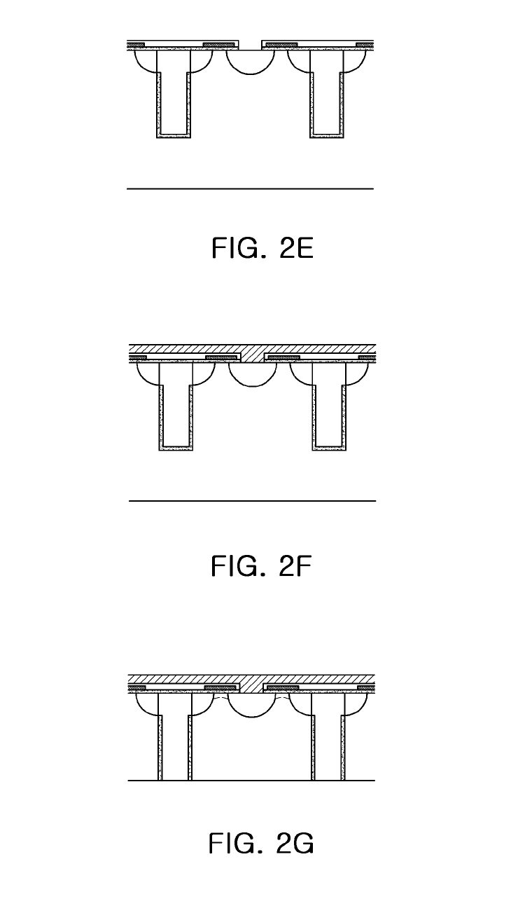

FIGS. 2A through 2G are views showing a process of manufacturing a power semiconductor device according to the exemplary embodiment of the present disclosure.

Referring to FIGS. 2A through 2G, a method of manufacturing a power semiconductor device according to the exemplary embodiment of the present disclosure may include: preparing a body region 10 having a via hole formed therein and having a first conductivity (See FIG. 2A); implanting impurities having a second conductivity into a portion of a surface of the body region 10 to form a well 20 and a source region 40 (See FIG. 2C); filling the via hole with polysilicon or metal to form a conductive via 30; and forming a gate part 50 on the conductive via 30 and the body region.

The method of manufacturing a power semiconductor device according to the exemplary embodiment of the present disclosure may further include removing a rear surface of the body region 10 so that the conductive via 30 is formed to penetrate through the body region 10 (See FIG. 2G).

The removing of the rear surface of the body region 10 (See FIG. 2G) may be performed after all of the processes required for a front surface of the body region 10 are finished.

The removing of the rear surface of the body region 10 (See FIG. 2G) may be performed by grinding or polishing.

In addition, a depth to which the rear surface is removed may be appropriately controlled.

The method of manufacturing a power semiconductor device according to the exemplary embodiment of the present disclosure may further include forming a via insulating film 31 between the conductive via 30 and the body region 10.

The via insulating film 31 may be formed by depositing an oxide after the preparing of the body region 10 the via hole formed therein (See FIG. 2A) is performed.

After the oxide is deposited, a portion of the deposited oxide may be removed using a mask in order to form the well 20 and the source region 40 (See FIG. 2B).

The forming of the gate part 50 (See FIGS. 2D and 2E) may include forming an oxide film. 52 on the power semiconductor device in which the well 20 and the source region 40 are formed, except for a portion of the source region 40; forming polysilicon 51 on the oxide film; and forming a dielectric 53 formed on the polysilicon 51.

The method of manufacturing a power semiconductor device according to the exemplary embodiment of the present disclosure may further include, after the forming of the gate part 50, forming a drain region in a lower portion of the body region 10.

The first conductivity and the second conductivity may be n-type conductivity and p-type conductivity, respectively, and vice versa.

As set forth above, according to the exemplary embodiments of the present disclosure, problems according to the related art may be solved.

More specifically, according to the exemplary embodiments of the present disclosure, a power semiconductor device of which a turn-on resistance is decreased by forming a conductive via may be provided.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device comprising:
a body region having a first conductivity;
a well formed in an upper portion of the body region and having a second conductivity; and
a conductive via formed in the body region while traversing the well.

2. The power semiconductor device of claim 1, wherein the conductive via provides a path along which current flows when the power semiconductor device is turned on.

3. The power semiconductor device of claim 1, wherein the conductive via is formed to penetrate through the body region.

4. The power semiconductor device of claim 1, further comprising a via insulating film formed between the conductive via and the body region.

5. The power semiconductor device of claim 1, wherein the conductive via is formed of at least one of polysilicon and a metal.

6. The power semiconductor device of claim 1, further comprising a source region formed at an upper portion of the body region, spaced apart from the well, and having the second conductivity.

7. The power semiconductor device of claim 6, further comprising a gate part on the well, the body region, and the source region.

8. The power semiconductor device of claim 1, further comprising a drain region formed in a lower portion of the body region.

9. The power semiconductor device of claim 1, wherein the first conductivity and the second conductivity are a p-type and an n-type, respectively.

10. A method of manufacturing a power semiconductor device, comprising:
preparing a body region having a via hole formed therein and having a first conductivity;
implanting impurities having a second conductivity into a portion of a surface of the body region in which a well is formed to form a source region;
filling the via hole with polysilicon or metal to form a conductive via; and
forming a gate part on the conductive via and the body region.

11. The method of claim 10, wherein the conductive via provides a path along which current flows when the power semiconductor device is turned on.

12. The method of claim 10, further comprising removing a rear surface of the body region so that the conductive via is formed to penetrate through the body region.

13. The method of claim 10, further comprising forming a via insulating film between the conductive via and the body region.

14. The method of claim 10, further comprising, after the forming of the gate part, forming a drain region in a lower portion of the body region.

15. The method of claim 10, wherein the first conductivity and the second conductivity are n-type conductivity and p-type conductivity, respectively.
